(19) United States
(12) Patent Application Publication
(10) Pub. No.: US 2026/0136770 A1
(43) Pub. Date: May 14, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Yunjie LIU, Hefei (CN); Manli CHEN, Kunshan (CN); Deng GAO, Hefei (CN); Xinge MENG, Hefei (CN); Tingxia HE, Hefei (CN)

(73) Assignees: Hefei Visionox Technology Co., Ltd., Hefei (CN); Visionox Technology Inc., Kunshan (CN)

(21) Appl. No.: 19/384,989

(22) Filed: Nov. 10, 2025

(30) Foreign Application Priority Data
Nov. 11, 2024 (CN) 202411607916.3

(51) Int. Cl. H10K 59/122

(52) U.S. Cl. CPC H10K 59/122

(57) ABSTRACT

The present application relates to the field of display technology and specifically provides a display panel and a display device. The display panel includes a substrate, a pixel definition layer, and a light-emitting functional layer. The pixel definition layer is disposed on a side of the substrate and provided with a pixel opening, and a side of the pixel definition layer facing the pixel opening is an opening sidewall. The light-emitting functional layer covers the pixel opening, and the opening sidewall is provided with at least one protrusion or at least one recess. The display panel can improve the bonding strength between the pixel definition layer and other film layers inside the pixel opening by providing the protrusion or recess on the opening sidewall of the pixel opening.

### CROSS-REFERENCE TO RELATED APPLICATIONS

The present application claims priority to the Chinese Patent Application No. 202411607916.3, filed on Nov. 11, 2024, and the entire contents of the aforementioned application are hereby incorporated by reference in its entirety.

### FIELD

The present application belongs to the field of display technology, and specifically, relates to a display panel and a display device.

### BACKGROUND

Organic Light Emitting Diode (OLED) and flat panel display devices based on Organic Light Emitting Diode (OLED) technology have been widely used in various consumer electronic products such as mobile phones, televisions, laptops, desktop computers, due to their advantages of high picture quality, power saving, thin body, and wide application range, becoming mainstream in display devices.

However, the performance of current OLED display products needs to be improved.

### SUMMARY

The present application provides a display panel and a display device to improve the performance of the display panel at least to some extent.

To achieve the above object, the solution adopted by the present application is:

An embodiment of the present application provides a display panel, including: a substrate, a pixel definition layer, and a light-emitting functional layer, and the pixel definition layer is provided with a pixel opening, a side of the pixel definition layer facing the pixel opening is an opening sidewall, the light-emitting functional layer covers the pixel opening, and the opening sidewall is provided with at least one protrusion or at least one recess.

An embodiment of the present application further provides a display device, including the display panel according to any one of the above embodiments.

The beneficial effects of the display panel and display device provided by the present application are: compared with related technology, the display panel provided by the present application can improve the bonding strength between the pixel definition layer and other film layers inside the pixel opening through the opening sidewall provided with at least one protrusion or at least one recess, effectively reducing the probability of delamination defects at the pixel opening and improving the reliability of the display panel. Additionally, with the firm connection between the pixel definition layer and related film layers, it can achieve the effect of reducing the probability of water and oxygen penetrating into the display panel through the pixel definition layer, avoiding pixel dark spot defects caused by water and oxygen erosion, thereby helping to improve the display effect and performance of the display panel. This structure can also improve the durability of the display panel to some extent, giving the display panel a longer service life.

### BRIEF DESCRIPTION OF THE DRAWINGS

FIG. 1 is a plan view of a display panel provided by one or more embodiments of the present application;

FIG. 2 is an enlarged view of the S1 area structure in the display panel shown in FIG. 1;

FIG. 3 is a sectional view along A-A direction of the display panel shown in FIG. 2 in one or more embodiments;

FIG. 4 is a sectional view along A-A direction of the display panel shown in FIG. 2 in one or more embodiments;

FIG. 5 is an enlarged view of area B structure in FIG. 4;

FIG. 6 is a plan view of a display device provided by one or more embodiments of the present application.

### LIST OF REFERENCE SIGNS

1—substrate; 2—pixel definition layer; 201—pixel opening; 21—opening sidewall; 2101—first edge; 2102—second edge; 22—uneven structure; 23—step; 231—third edge; 232—first connecting wall; 233—second connecting wall; 3—light—emitting functional layer; 4—isolation structure; 401—isolation opening; 41—root portion; 42—support portion; 43—crown portion; 5—first electrode layer; 6—second electrode layer; 7—encapsulation layer; 71—first encapsulation portion; 72—second encapsulation portion; 73—third encapsulation portion;
10—display panel;
100—display device.

### Detailed Description of the Embodiments

To make the embodiments of the present application clearer, the present application will be further described in detail with reference to the drawings and embodiments. It should be understood that the specific embodiments described herein are merely used to explain the present application and are not intended to limit the present application.

It should be noted that when an element is referred to as being “fixed to” or “disposed on” another element, it can be directly on the other element or indirectly on that other element. When an element is referred to as being “connected to” another element, it can be directly connected to the other element or indirectly connected to that other element.

In the description of the present application, it should be understood that terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and other directional or positional relationships are based on the orientations or positional relationships shown in the drawings, and are only for the convenience of description and simplification of the present application, and do not indicate or imply that the referred device or element must have a specific orientation, be constructed or operated in a specific orientation, and therefore should not be understood as limitations of the present application.

Furthermore, the terms “first”, “second” are only used for descriptive purposes and cannot be understood as indicating or implying relative importance or implicitly indicating the number of features indicated. Thus, features defined as “first”, “second” may explicitly or implicitly include one or more of these features. In the description of the present application, “plurality” means two or more unless explicitly specified otherwise.

In the present application, unless otherwise explicitly specified and limited, terms such as “installed”, “connected”, “connected”, “fixed” should be understood broadly. For example, they can be fixed connection or detachable connection, or integrated; they can be mechanical connection or electrical connection or communicable with each other; they can be directly connected or indirectly connected through intermediate media, they can be internal communication between two elements or interaction relationship between two elements, unless otherwise explicitly limited. The specific meaning of the above terms in the present application can be understood according to specific situations.

In the present application, unless otherwise explicitly specified and limited, when a first feature is “on” or “under” a second feature, the first and second features may be in direct contact, or the first and second features may be in indirect contact through intermediate media. Moreover, “above”, “over” and “on top of” the second feature for the first feature can mean the first feature is directly above or obliquely above the second feature, or merely indicate that the horizontal height of the first feature is higher than the second feature. “Below”, “under” and “beneath” the second feature for the first feature can mean the first feature is directly below or obliquely below the second feature, or merely indicate that the horizontal height of the first feature is lower than the second feature.

In the present application, terms such as “an embodiment”, “some embodiments”, “example”, “specific example”, or “some examples” mean that specific features, structures, materials, or characteristics described in connection with the embodiment or example are included in at least one embodiment or example of the present application. In this specification, the exemplary representations of the above terms do not necessarily refer to the same embodiment or example. Moreover, the described specific features, structures, materials, or characteristics may be combined in any suitable manner in one or more embodiments or examples. Furthermore, under non-contradictory circumstances, different embodiments or examples and features of different embodiments or examples described in this specification may be combined.

The term “layer” used in the text may refer to a material portion including a region with a certain thickness. A layer may extend over the entire underlying structure or overlying structure, or may have a range smaller than that of the underlying or overlying structure. Furthermore, a layer may be a region of a homogeneous or non-homogeneous continuous structure with a thickness less than that of the continuous structure. For example, a layer may be located between the top surface and bottom surface of said continuous structure or between any pair of horizontal planes at said top surface and bottom surface. A layer may extend laterally, vertically, and/or along a conical surface. A substrate may be a layer, may include one or more layers, and/or may have one or more layers on it, above it, and/or below it. A layer may include a plurality of layers. For example, an interconnection layer may include one or more conductor and contact layers (in which contacts, interconnection lines, and/or vias are formed) and one or more dielectric layers.

The display panel 10 is provided with an isolation structure 4, which can be used to isolate some functional film layers in adjacent light-emitting units (also called light-emitting devices), ensuring that adjacent light-emitting units do not interfere with each other, helping to improve the display effect of the display panel 10. However, in related technology, it has been found that some light-emitting units have dark spot defects, which to some extent affects the display effect of the display panel 10 and ultimately affects its performance.

Based on this, the embodiments of the present application provide a display panel 10 to at least partially alleviate or improve the above problems.

The present application provides a display panel 10 and a display device 100 to improve the performance of the display panel 10 at least to some extent, giving it better display effects and better service life.

The display panel 10 includes a substrate 1 and a pixel definition layer 2 located on the substrate 1. A pixel opening 201 is formed in the pixel definition layer 2, and the pixel opening 201 penetrates through two surfaces of the pixel definition layer 2 in a thickness direction. An opening sidewall 21 is formed on the side of the pixel definition layer 2 facing the pixel opening 201, and the opening sidewall 21 is provided with at least one protrusion or at least one recess, or the opening sidewall 21 is provided with at least one protrusion and at least one recess. The opening sidewall 21 is provided with a plurality of protrusions or a plurality of recesses, or the opening sidewall 21 is provided with a plurality of protrusions and a plurality of recesses, where the protrusions or recesses refer to surface roughness, surface unevenness, surface undulation, waves, or surface step protrusions, etc.

The above opening sidewall 21 can enclose to form the pixel opening 201. In the display panel 10 provided by the embodiments of the present application, by providing protrusions or recesses on the opening sidewall 21 of the pixel opening 201, the bonding strength between the pixel definition layer 2 and other film layers inside the pixel opening 201 can be improved, making other film layers connected to the pixel definition layer 2 through the opening sidewall 21 require greater peeling force to delaminate from the pixel definition layer 2, reducing the probability of delamination defects at the pixel opening 201, helping to improve the reliability of the display panel 10, and effectively reducing failures due to film layer delamination at the pixel opening 201 affecting its encapsulation effect. Additionally, by reducing film layer delamination defects at the pixel opening 201 of the display panel 10, it can further reduce the possibility of water and oxygen penetrating through gaps caused by delamination at the pixel opening 201 and eroding related light-emitting units, leading to display defects and affecting the display effect of the display panel 10. This solution helps improve the performance of the display panel.

In one or more embodiments, the pixel definition layer 2 can contact and connect with other adjacent film layers through the opening sidewall 21. By roughening the opening sidewall 21, the bonding strength between the pixel opening 201 of the pixel definition layer 2 and adjacent film layers can be effectively improved, making their connection more secure and less prone to delamination, thereby avoiding delamination defects between the film layers contacting the pixel definition layer 2 through the pixel opening 201 and the pixel definition layer 2.

The above structure can effectively improve the reliability and service life of the display panel 10, and to some extent reduce the probability of pixel dark spot defects in the display panel 10, improving the display effect of the display panel 10.

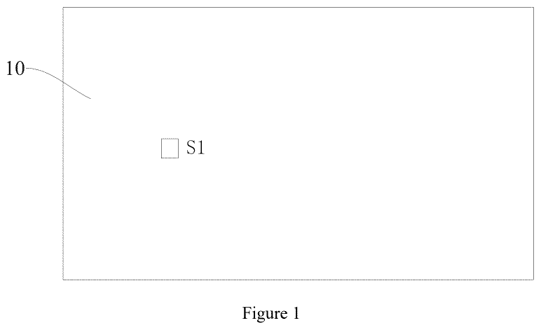

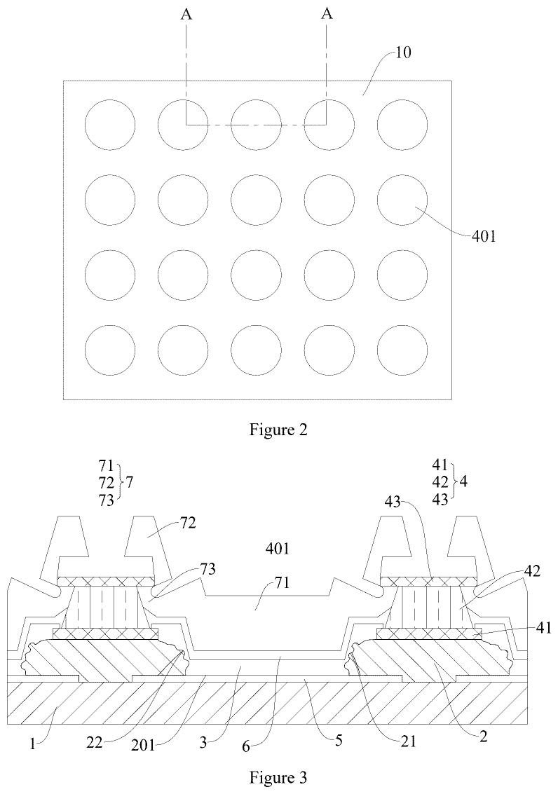

In some embodiments, referring to FIGS. 1-3, the display panel 10 further includes a light-emitting functional layer 3, which is located on a side of the pixel definition layer 2 facing away from the substrate 1, and the orthographic projection of the light-emitting functional layer 3 on the substrate 1 partially overlaps with the orthographic projection of the pixel opening 201 on the substrate 1.

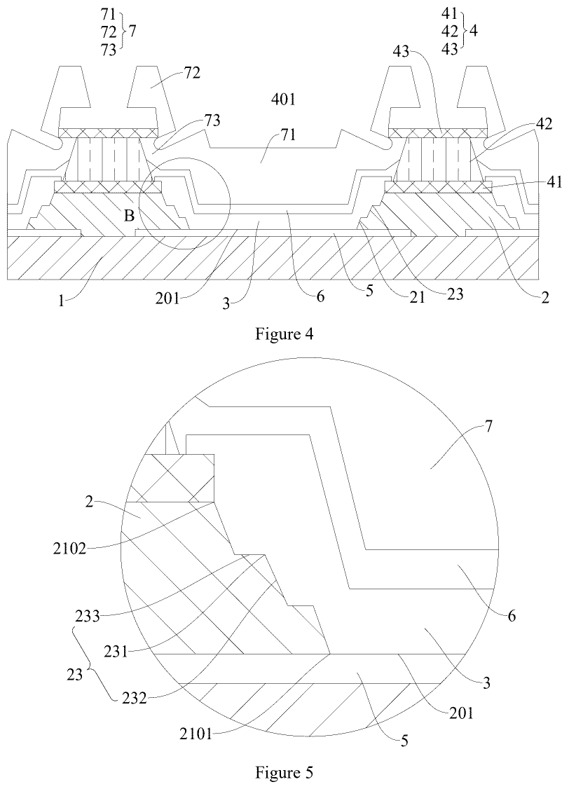

Referring to FIGS. 3-4, the light-emitting functional layer 3 is connected to the pixel definition layer 2 through the opening sidewall 21. The light-emitting functional layer 3 at least partially covers the opening sidewall 21.

For example, a portion of the peripheral sidewall of the light-emitting functional layer 3 contacts the opening sidewall 21 of the pixel opening 201. In this case, the pixel definition layer 2 can connect with the light-emitting functional layer 3 through the roughened opening sidewall 21 to improve the bonding strength between them, making them less prone to delamination, thereby effectively preventing delamination defects between the pixel definition layer 2 and the light-emitting functional layer 3, improving the reliability of the display panel 10.

In some embodiments, compared with traditional smooth sidewall structures, the roughened design of the opening sidewall 21 can increase the contact area between the pixel definition layer 2 and the light-emitting functional layer 3 without changing the size of the pixel opening 201, the thickness of the pixel definition layer 2, and the thickness of the light-emitting functional layer 3, thereby improving the bonding strength between the pixel definition layer 2 and the light-emitting functional layer 3, and consequently increasing the peeling force required for the light-emitting functional layer 3 to delaminate from the pixel definition layer 2, reducing the possibility of delamination between them.

It can be understood that the greater the peeling force of the light-emitting functional layer 3, the more difficult it is to be delaminated.

To enable the light-emitting functional layer 3 to work normally under electrified conditions, the display panel 10 also includes a first electrode layer 5 and a second electrode layer 6.

Referring to FIGS. 3 and 4, the first electrode layer 5, the light-emitting functional layer 3, and the second electrode layer 6 are sequentially stacked on the substrate 1, and the first electrode layer 5 is located between the substrate 1 and the pixel definition layer 2, a portion of the first electrode layer 5 is exposed through the pixel opening 201 and connected to the light-emitting functional layer 3, and the second electrode layer 6 is located on a side of the light-emitting functional layer 3 facing away from the substrate 1.

The orthographic projection of the first electrode layer 5 on the substrate 1 partially overlaps with the orthographic projection of the pixel opening 201 on the substrate 1. The light-emitting functional layer 3 covers at least a portion of the pixel opening 201 and contacts the first electrode layer 5 located between the pixel definition layer 2 and the substrate 1 through the pixel opening 201. The second electrode layer 6 covers the surface of the light-emitting functional layer 3 facing away from the substrate 1.

For example, the first electrode layer 5 can be an anode layer, and correspondingly, the second electrode layer 6 is a cathode layer. Of course, in other embodiments, the first electrode layer 5 can also be set as a cathode layer and the second electrode layer 6 as an anode layer.

The stacked first electrode layer 5, light-emitting functional layer 3, and second electrode layer 6 can work together to achieve light emission under electrified conditions.

In this embodiment or other similar embodiments, the light-emitting functional layer 3 does not cover all of the opening sidewall 21 of the pixel opening 201, and at this time, a portion of the second electrode layer 6 in the circumferential direction can contact part of the opening sidewall 21 of the pixel opening 201.

The pixel definition layer 2 can connect with the second electrode layer 6 through the roughened opening sidewall 21 to improve the bonding strength between the pixel definition layer 2 and the second electrode layer 6, making them less prone to delamination, thereby effectively preventing delamination defects between the pixel definition layer 2 and the second electrode layer 6, improving the reliability of the display panel 10.

The content of the isolation structure 4 mentioned below is further described in patents CN118251982A, patent 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, CN117500332A for reference.

Referring to FIG. 3, in some embodiments, the display panel 10 further includes an isolation structure 4, and the isolation structure 4 is located on a side of the pixel definition layer 2 facing away from the substrate 1. An isolation opening 401 is formed in the isolation structure 4, and the pixel opening 201 corresponds to and communicates with the isolation opening 401. The orthographic projection of the pixel opening 201 on the substrate 1 is located within the range of the orthographic projection of the isolation opening 401 on the substrate 1.

The light-emitting functional layer 3 is located within the isolation opening 401, and the portion of the light-emitting functional layer 3 that extends beyond the pixel opening 201 can connect with the isolation structure 4. In other words, a peripheral portion of the light-emitting functional layer 3 connects with the isolation structure 4, though it may also not connect, which can better prevent the occurrence of current leakage phenomena; specific details are not limited here.

At least a portion of the second electrode layer 6 in the circumferential direction on the side of the light-emitting functional layer 3 facing away from the substrate 1 can overlap with (for example, also can contact) the isolation structure 4.

In some embodiments, the display panel 10 further includes an encapsulation layer 7, which is located on the side of the light-emitting functional layer 3 facing away from the substrate 1. At least a portion of the encapsulation layer 7 is located within the isolation opening 401 and can cover the light-emitting functional layer 3.

For example, the encapsulation layer 7 is located on the side of the second electrode layer 6 facing away from the substrate 1, and at least a portion of the encapsulation layer 7 is located within the isolation opening 401 and can cover the second electrode layer 6.

During reliability testing, the encapsulation layer 7 may expand or contract due to temperature increases or decreases. During the deformation process of the encapsulation layer 7, it will be constrained by the isolation opening 401 and generate certain stress. This stress will be released under certain conditions, at which time at least one of the light-emitting functional layer 3 and the second electrode layer 6 may be affected by this stress and develop delamination defects between them and the opening sidewall 21 of the pixel definition layer 2, making it easier for external water and oxygen to penetrate into the display panel 10 and affect its service life, or even cause pixel dark spot defects. In the embodiments of the present application, by roughening the opening sidewall 21, the bonding strength between either the light-emitting functional layer 3 or the second electrode layer 6 and the isolation opening 401 can be effectively improved, thereby increasing the peeling force required for either layer to delaminate from the pixel definition layer 2, reducing the possibility of delamination between connected film layers.

Therefore, the above design can effectively prevent delamination defects between either the light-emitting functional layer 3 or the second electrode layer 6 and the pixel definition layer 2.

In this embodiment or other similar embodiments, neither the light-emitting functional layer 3 nor the second electrode layer 6 covers all of the opening sidewall 21 of the pixel opening 201. At this time, the portion of the encapsulation layer 7 located within the isolation opening 401 and covering the second electrode layer 6 can contact part of the opening sidewall 21 formed in the pixel opening 201.

The pixel definition layer 2 can connect with the encapsulation layer 7 through the roughened opening sidewall 21 to improve the bonding strength between them, making them less prone to delamination, thereby effectively preventing delamination defects between them and improving the reliability of the display panel 10.

In some embodiments, the roughened opening sidewall 21 can be prepared by etching or formed by ion bombardment or other methods.

For example, the roughened opening sidewall 21 can present an uneven morphology.

Referring to FIG. 3, an uneven structure 22 is provided on the opening sidewall 21, which can make the opening sidewall 21 present an uneven, rough state. At this time, the roughened opening sidewall 21 can increase the contact area between the opening sidewall 21 and the light-emitting functional layer 3 through several uneven structures 22 protruding toward the pixel opening 201, improving their bonding strength and reducing the possibility of film layer delamination defects between the pixel definition layer 2 and the light-emitting functional layer 3.

For example, the number of uneven structures 22 can be one or more. When there are a plurality of uneven structures 22, the plurality of uneven structures 22 can be arranged at intervals along the thickness direction of the pixel definition layer 2, or arranged at intervals along the circumferential direction of the pixel opening 201, or the plurality of uneven structures 22 can be arranged at intervals along the thickness direction of the pixel definition layer 2, and arranged at intervals along the circumferential direction of the pixel opening 201.

For example, the uneven structures 22 are distributed at various different positions on the opening sidewall 21 to further improve the bonding strength between the pixel definition layer 2 and other adjacent film layers connected through the opening sidewall 21.

The uneven structures 22 can be formed by chemical etching or physical treatment methods.

In other similar embodiments, at least one step 23 projecting toward (or facing toward) the pixel opening 201 can also be provided on the opening sidewall 21, as shown in FIG. 4. The step 23 can make the opening sidewall 21 present an uneven, rough state.

The roughened opening sidewall 21 can achieve the effect of increasing the contact area between the opening sidewall 21 and other adjacent film layers connected through the opening sidewall 21 through several steps 23 protruding toward the pixel opening 201, and improve their bonding strength, reducing the possibility of film layer delamination defects between the pixel definition layer 2 and either the light-emitting functional layer 3 or the second electrode layer 6.

For example, the step 23 can also be called a “Taper angle”, which is formed in an area where the external shape of a structure gradually becomes thinner or sharper. From the cross-section of the structure, if the cross-sectional area gradually decreases along a certain direction, a Taper angle may exist in that direction. The step 23 can make the surface structure of the opening sidewall 21 complex and variable, forming a relatively roughened surface.

Referring to FIG. 5, the opening sidewall 21 includes a first edge 2101 adjacent to the substrate 1 and a second edge 2102 facing away from the substrate 1, with the step 23 disposed between the first edge 2101 and the second edge 2102 and pointing toward the pixel opening 201.

The opening sidewall 21 with the first edge 2101 and the second edge 2102 is a slope surface arranged at an incline relative to the plane where the substrate 1 is located, and the end facing away from the substrate 1 inclines toward the direction away from the pixel opening 201.

For example, in a cross section along the thickness direction of the substrate 1, the angle between the line connecting the first edge 2101 and the second edge 2102 and the plane where the substrate 1 is located is between 30° and 75°, and its specific value range can be adjusted according to actual needs. For example, this angle can be any value among 30°, 35°, 40°, 45°, 50°, 55°, 60°, 65°, 70°, 75°, etc.

In some embodiments, the cross-section of the opening sidewall 21 formed by several steps 23 is similar to a stepped structure.

Referring to FIG. 5, the end of the step 23 pointing toward the pixel opening 201 forms a third edge 231, which is located between the first edge 2101 and the second edge 2102. The third edge 231 is actually arc-shaped in practical process, and the illustration is just an example.

In some embodiments, the orthographic projection of the third edge 231 on the substrate 1 is located between the orthographic projection of the first edge 2101 on the substrate 1 and the orthographic projection of the second edge 2102 on the substrate 1.

In other embodiments, the orthographic projection of the third edge 231 on the substrate 1 can also be set on the side of the orthographic projection of the first edge 2101 toward the center of the pixel opening 201, at which time the third edge 231 is closer to the center of the pixel opening 201 relative to the first edge 2101.

It should be noted that the number of third edges 231 is the same as the number of steps 23 and they are arranged in one-to-one correspondence.

Referring to FIG. 5, the step 23 also includes a first connecting wall 232 and a second connecting wall 233, with the third edge 231 located at the intersection of the first connecting wall 232 and the second connecting wall 233. The first connecting wall 232, second connecting wall 233, and third edge 231 work together to form the step 23 structure on the surface of the opening sidewall 21.

The number of steps 23 can be one, two, or even more.

When there is only one step 23, this step 23 can connect to the first edge 2101 of the opening sidewall 21 through the first connecting wall 232, and to the second edge 2102 of the opening sidewall 21 through the second connecting wall 233. In other words, the end of the first connecting wall 232 facing away from the third edge 231 forms the first edge 2101, and the end of the second connecting wall 233 facing away from the third edge 231 forms the second edge 2102.

In some embodiments, the at least one step 23 includes at least two steps, the number of steps 23 is at least two, and all steps 23 are arranged sequentially at intervals in a direction away from the substrate 1. At this time, any two adjacent steps 23 can be connected through sequentially connected second connecting wall 233 and first connecting wall 232. At least part of the opening sidewall 21 presents a segmented multi-Taper angle design, for example: the pixel definition layer 2 includes a multi-layer structure, and there are deviations between layers during etching leading to steps or stairs, and the multi-layer structure can be of the same material or different materials.

When there are two steps 23, the step 23 closer to the substrate 1 can connect to the first edge 2101 of the opening sidewall 21 through the first connecting wall 232, and the step 23 facing away from the substrate 1 can connect to the second edge 2102 of the opening sidewall 21 through the second connecting wall 233. Adjacent steps 23 are connected through their corresponding second connecting wall 233 and first connecting wall 232, and a relatively sharp angle can be formed between the second connecting wall 233 and the first connecting wall 232 to further increase the roughness of the opening sidewall 21. Of course, the adjacent second connecting wall 233 and first connecting wall 232 can also be connected through a relatively smooth curved surface.

When there are three steps 23, referring to FIG. 5, the middle step 23 connects to the second connecting wall 233 and first connecting wall 232 of the other two steps 23 through its first connecting wall 232 and second connecting wall 233 respectively.

For example, the steps 23 are distributed at various different positions on the opening sidewall 21 to further improve the bonding strength between the pixel definition layer 2 and adjacent film layers.

When there are at least two steps 23, for any two adjacent steps 23, along the thickness direction of the substrate 1, the step 23 closer to the second edge 2102 is located on the side of the step 23 closer to the first edge 2101 facing away from the pixel opening 201.

Referring to FIGS. 4 and 5, the opening sidewall 21 formed around the pixel opening 201 appears as an inclined slope in the cross-sectional direction of the display panel 10, and each step 23 is arranged sequentially at intervals along the inclined direction.

For any two adjacent steps 23, the step 23 farther from the substrate 1 is closer to the second edge 2102 compared to the step 23 closer to the substrate 1.

For example, for any two steps 23, along the thickness direction of the substrate 1, the distance between the orthographic projection of the step 23 closer to the first edge 2101 on the substrate 1 and the orthographic projection of the first edge 2101 on the substrate 1 is a first distance; the distance between the orthographic projection of the step 23 closer to the second edge 2102 on the substrate 1 and the orthographic projection of the first edge 2101 on the substrate 1 is a second distance. The first distance is smaller than the second distance.

Under other unchanged conditions, when the opening sidewall 21 with the above uneven structure 22 or step 23 contacts any of the light-emitting functional layer 3, second electrode layer 6, and encapsulation layer 7, or the opening sidewall 21 with the above uneven structure 22 and step 23 contacts any of the light-emitting functional layer 3, second electrode layer 6, and encapsulation layer 7, it can effectively improve the bonding strength between the pixel definition layer 2 and related film layers.

Taking the light-emitting functional layer 3 as an example, when the opening sidewall 21 with the above uneven structure 22 or step 23 contacts the light-emitting functional layer 3, or the opening sidewall 21 with the above uneven structure 22 and step 23 contacts the light-emitting functional layer 3, it can effectively improve the bonding strength between the pixel definition layer 2 and the light-emitting functional layer 3, making the force between the pixel definition layer 2 and the light-emitting functional layer 3 greater than the force between the light-emitting functional layer 3 and the encapsulation layer 7, thereby effectively avoiding delamination defects of the light-emitting functional layer 3 relative to the pixel opening 201 of the pixel definition layer 2 due to stress from the encapsulation layer 7.

Taking the second electrode layer 6 as an example, when the opening sidewall 21 with the above uneven structure 22 or step 23 contacts the second electrode layer 6, or the opening sidewall 21 with the above uneven structure 22 and step 23 contacts the second electrode layer 6, it can effectively improve the bonding strength between the pixel definition layer 2 and the second electrode layer 6, making the force between the pixel definition layer 2 and the second electrode layer 6 greater than the force between the second electrode layer 6 and the encapsulation layer 7, thereby effectively avoiding delamination defects of the second electrode layer 6 relative to the pixel opening 201 of the pixel definition layer 2 due to stress from the encapsulation layer 7.

Taking the encapsulation layer 7 as an example, when the opening sidewall 21 with the above uneven structure 22 or step 23 contacts the encapsulation layer 7, or the opening sidewall 21 with the above uneven structure 22 and step 23 contacts the encapsulation layer 7, it can effectively improve the bonding strength between the pixel definition layer 2 and the encapsulation layer 7, increasing the force between the pixel definition layer 2 and the encapsulation layer 7, avoiding delamination defects of the encapsulation layer 7 relative to the pixel opening 201 of the pixel definition layer 2 due to stress.

Referring to FIGS. 3 and 4, in the isolation structure 4 provided by the embodiments of the present application, the isolation structure 4 between adjacent isolation openings 401 includes sequentially stacked a root portion 41, a support portion 42, and a crown portion 43, and the root portion 41 is disposed on the side of the substrate 1, the support portion 42 is located on a side of the root portion 41 facing away from the substrate 1, the crown portion 43 is located on a side of the support portion 42 facing away from the root portion 41, and the isolation opening 401 penetrates through the crown portion 43, support portion 42, and root portion 41 and communicates with the pixel opening 201 of the pixel definition layer 2.

In some embodiments, the peripheral portion of the light-emitting functional layer 3 contacting the pixel definition layer 2 through the pixel opening 201 can connect with the isolation structure 4. However, to prevent current leakage, the light-emitting functional layer 3 may completely avoid connecting with the isolation structure 4.

The light-emitting functional layer 3 includes a plurality of film layers sequentially stacked along the thickness direction of the substrate 1, and some film layers on the side facing away from the substrate 1 can contact part of the sidewall of the isolation structure 4 facing the isolation opening 401, while some film layers closer to the substrate 1 can contact at least part of the surface of the opening sidewall 21 and maintain a certain distance from the isolation structure 4.

For example, the light-emitting functional layer 3 includes a Hole Block Layer (HBL), a Emission Layer (EML), a Prime Layer (optical adjustment layer), and a Hole Injection Layer (HIL) sequentially stacked along the thickness direction. The HIL covers the pixel opening 201 and part of the surface of the pixel definition layer 2 facing away from the substrate 1, maintaining a gap with the isolation structure 4; the Prime Layer covers the surface of the HIL facing away from the substrate 1; the EML covers the surface of the Prime Layer facing away from the HIL; the HBL covers the surface of the EML facing away from the Prime Layer and can contact part of the sidewall of the isolation structure 4 facing the isolation opening 401.

The materials of various film layers constituting the light-emitting functional layer 3 can refer to information already disclosed in related technology, which will not be detailed in this application.

Referring to FIGS. 3 and 4, part of the film layers on the side of the light-emitting functional layer 3 facing away from the substrate 1 can contact part of the sidewall of the isolation structure 4 closer to the substrate 1; the second electrode layer 6 covers the surface of the light-emitting functional layer 3 facing away from the substrate 1 and contacts part of the sidewall of the isolation structure 4.

For example, the light-emitting functional layer 3 can overlap with (for example, also can contact with) part of the outer sidewall of the root portion 41 of the isolation structure 4; the second electrode layer 6 can overlap with (for example, also can contact with) part of the outer sidewall of the root portion 41 of the isolation structure 4, or the second electrode layer 6 can overlap with (for example, also can contact with) part of the outer sidewall of the support portion 42 closer to the substrate 1, or the second electrode layer 6 can overlap with (for example, also can contact with) part of the outer sidewall of the root portion 41 of the isolation structure 4, and the second electrode layer 6 can overlap with (for example, also can contact with) part of the outer sidewall of the support portion 42 closer to the substrate 1.

In other similar embodiments, there can be a gap between the orthographic projection of the light-emitting functional layer 3 on the substrate 1 and the orthographic projection of the end of the isolation structure 4 closer to the substrate 1. In this case, the light-emitting functional layer 3 does not connect with the isolation structure 4, and the second electrode layer 6 can overlap with (for example, also can contact with) the root portion 41 of the isolation structure 4, or simultaneously overlap with (for example, also can contact with) both the root portion 41 and support portion 42 of the isolation structure 4.

In some embodiments, the crown portion 43 extends outward along the sidewall of the support portion 42.

For example, the orthographic projection of the end of the support portion 42 closer to the crown portion 43 on the substrate 1 is located within the range of the orthographic projection of the crown portion 43 on the substrate 1.

In some cases, the orthographic projection of the support portion 42 on the substrate 1 is located within the range of the orthographic projection of the crown portion 43 on the substrate 1; in other cases, the orthographic projection of the crown portion 43 on the substrate 1 is located within the range of the orthographic projection of the end of the support portion 42 closer to the substrate 1 on the substrate 1.

The cross-section of the support portion 42 can be a trapezoidal or near-trapezoidal structure.

For example, the cross-section of the support portion 42 is a regular trapezoid structure, and the cross-sections of the root portion 41 and crown portion 43 on both sides of the support portion 42 in the thickness direction can be trapezoidal, rectangular, or other similar structures.

In some embodiments, the root portion 41, support portion 42, and crown portion 43 can be an integrally formed structure, or can be formed by stacking different material layers.

For example, the crown portion 43 is made of titanium metal, forming a titanium metal layer; the support portion 42 is made of aluminum metal, forming an aluminum metal layer; the root portion 41 is made of molybdenum metal, forming a molybdenum metal layer.

Referring to FIGS. 3-4, the portion of the encapsulation layer 7 within the isolation opening 401 covers the side of the second electrode layer 6 facing away from the substrate 1, and the portion of the encapsulation layer 7 outside the isolation opening 401 is located on the side of the isolation structure 4 facing away from the substrate 1.

In one or more embodiments, the encapsulation layer 7 includes sequentially connected a first encapsulation portion 71, a second encapsulation portion 72, and a third encapsulation portion 73. The first encapsulation portion 71 is located within the isolation opening 401 and covers the side of the second electrode layer 6 facing away from the substrate 1, the second encapsulation portion 72 is located on the side of the isolation structure 4 facing away from the substrate 1, and the third encapsulation portion 73 connects the first encapsulation portion 71 and the second encapsulation portion 72 and covers the sidewall of the isolation structure 4 facing the isolation opening 401.

In one or more embodiments, the third encapsulation portion 73 covers part of the circumferential sidewall of the support portion 42 and extends along the sidewall of the support portion 42 to the crown portion 43, cooperating with the first encapsulation portion 71 to achieve encapsulation of related film layers within the isolation opening 401. The third encapsulation portion 73 connects with the second encapsulation portion 72 located on the side of the isolation structure 4 facing away from the substrate 1. One end of the second encapsulation portion 72 connects with the third encapsulation portion 73, and the other end extends toward the side of the isolation structure 4 away from the isolation opening 401 with an appropriate length to further ensure the encapsulation effect of the encapsulation layer 7 on the film layers within the corresponding isolation opening 401.

The previously mentioned encapsulation layer 7 can connect with the opening sidewall 21 provided with uneven structure 22 or step 23 through the first encapsulation portion 71, or the previously mentioned encapsulation layer 7 can connect with the opening sidewall 21 provided with uneven structure 22 and step 23 through the first encapsulation portion 71.

In some embodiments, the second encapsulation portion 72 is arranged at intervals with the surface of the isolation structure 4 facing away from the substrate 1, at which time at least part of the second encapsulation portion 72 is suspended relative to the isolation structure 4, and there is a gap between the second encapsulation portion 72 and the surface of the isolation structure 4 facing away from the substrate 1.

In some embodiments, the display panel 10 further includes a planarization layer and a second encapsulation layer, and the planarization layer covers the encapsulation layer 7 and has a relatively flat surface on the side away from the substrate 1. The second encapsulation layer is located on the side of the planarization layer away from the substrate 1 and covers the planarization layer.

Taking the planarization layer as an example, its material can include at least one of organic materials or inorganic materials. For example, organic polymers (such as polyimide, acrylic resin, etc.) or inorganic materials (such as silicon oxide, silicon nitride, etc.).

The planarization layer made of organic materials can be prepared using technologies such as IJP (Ink-Jet Printing). Part of the planarization layer can flow into the isolation opening 401 and the gap formed between the second encapsulation portion 72 and the isolation structure 4, improving the flatness of the display panel 10 by filling the isolation opening 401, while also providing some protection for the related film layers underneath.

The display panel 10 provided by one or more embodiments of the present application can improve the bonding strength between the pixel definition layer 2 and the light-emitting functional layer 3 inside the pixel opening 201 through the opening sidewall 21 provided with protrusions and recesses, effectively reducing the probability of delamination defects of the light-emitting functional layer 3 at the pixel opening 201, improving the reliability of the display panel 10. Additionally, with the firm connection between the pixel definition layer 2 and the light-emitting functional layer 3, it can achieve the effect of reducing the probability of water and oxygen penetrating into the display panel 10 through the pixel definition layer 2, avoiding pixel dark spot defects caused by water and oxygen erosion, helping to improve the display effect and performance of the display panel 10. This structure can also improve the durability of the display panel 10 to some extent, giving the display panel 10 a longer service life.

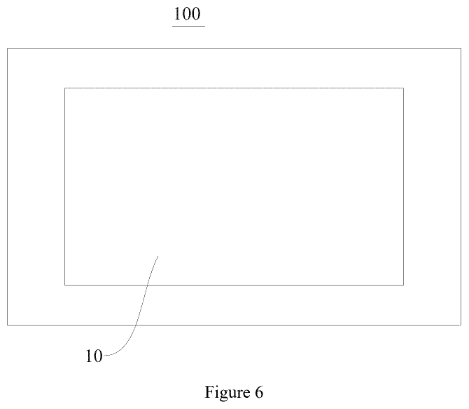

One or more embodiments of the present application also provides a display device 100, referring to FIG. 6. The display device 100 includes the display panel 10 according to any of the above embodiments.

The display device 100 provided in this embodiment can be products or components with display functions such as mobile phones, laptops, tablets, smart watches, smart bands, navigation devices, displays, Personal Digital Assistants (PDA), etc. Since the display panel 10 in the display device 100 has one or several beneficial effects of the above display panels, specific effects refer to the specific descriptions in the previous embodiments, which will not be repeated here.

The above description is only some embodiments of the present application and is not used to limit the present application. Any modifications, equivalent replacements, and improvements made within the spirit and principles of the present application should be included in the protection scope of the present application.

1. A display panel, comprising:
a substrate;
a pixel definition layer disposed on a side of the substrate and provided with a pixel opening, a sidewall of the pixel opening being an opening sidewall; and
a light-emitting functional layer covering the pixel opening;
wherein the opening sidewall is provided with at least one protrusion or at least one recess.

2. The display panel according to claim 1, wherein an uneven structure is provided on the opening sidewall.

3. The display panel according to claim 2, wherein the uneven structure is a burr or a wave structure.

4. The display panel according to claim 1, wherein at least one step projecting toward the pixel opening is provided on the opening sidewall.

5. The display panel according to claim 4, wherein the opening sidewall comprises a first edge adjacent to the substrate and a second edge facing away from the substrate;
the step is disposed between the first edge and the second edge.

6. The display panel according to claim 5, wherein in a cross section along a thickness direction of the substrate, an angle between a line connecting the first edge and the second edge and a plane where the substrate is located is between 30° and 75°.

7. The display panel according to claim 5, wherein the step comprises a third edge, the third edge is located between the first edge and the second edge, an orthographic projection of the third edge on the substrate is located between an orthographic projection of the first edge on the substrate and an orthographic projection of the second edge on the substrate.

8. The display panel according to claim 7, wherein the step further comprises a first connecting wall and a second connecting wall, the third edge is located at an intersection of the first connecting wall and the second connecting wall;
the first connecting wall of the step is connected to the first edge, and the second connecting wall is connected to the second edge.

9. The display panel according to claim 5, wherein the at least one step comprises at least two steps, and all the steps are arranged sequentially at intervals in a direction away from the substrate.

10. The display panel according to claim 9, wherein along a thickness direction of the substrate, for any two adjacent steps, the step closer to the second edge is located on a side of the step closer to the first edge facing away from the pixel opening.

11. The display panel according to claim 10, wherein the pixel definition layer comprises a multi-layer structure.

12. The display panel according to claim 1, wherein the light-emitting functional layer at least partially covers the opening sidewall and is connected to the pixel definition layer.

13. The display panel according to claim 12, wherein the display panel further comprises an isolation structure, the isolation structure is located on a side of the pixel definition layer facing away from the substrate, an isolation opening is formed in the isolation structure, the pixel opening corresponds to and communicates with the isolation opening;
an orthographic projection of the pixel opening on the substrate is located within a range of an orthographic projection of the isolation opening on the substrate.

14. The display panel according to claim 13, wherein the isolation structure comprises a root portion, a support portion, and a crown portion, the support portion is located on a side of the root portion facing away from the substrate, the crown portion is located on a side of the support portion facing away from the root portion;
the crown portion extends outward along a sidewall of the support portion.

15. The display panel according to claim 12, wherein the display panel further comprises a first electrode layer and a second electrode layer, the first electrode layer, the light-emitting functional layer, and the second electrode layer are sequentially stacked on the substrate;
the first electrode layer is located between the substrate and the pixel definition layer, a portion of the first electrode layer is exposed through the pixel opening and connected to the light-emitting functional layer;
the second electrode layer is located on a side of the light-emitting functional layer facing away from the substrate and overlaps with an isolation structure.

16. The display panel according to claim 15, wherein the second electrode layer further comprises an encapsulation layer, a morphology of the second electrode layer and the encapsulation layer above the pixel opening is consistent with the pixel opening.

17. A display device, comprising:
a display panel, comprising:
a substrate;
a pixel definition layer disposed on a side of the substrate and provided with a pixel opening, a sidewall of the pixel opening being an opening sidewall; and
a light-emitting functional layer covering the pixel opening;
wherein the opening sidewall is provided with at least one protrusion or at least one recess.

18. The display device according to claim 17, wherein an uneven structure is provided on the opening sidewall.

19. The display device according to claim 18, wherein the uneven structure is a burr or a wave structure.

20. The device panel according to claim 17, wherein at least one step projecting toward the pixel opening is provided on the opening sidewall.
